(19) United States
(12) Patent Application Publication
(10) Pub. No.: US 2006/0019025 A1
(43) Pub. Date: Jan. 26, 2006

(54) Method for test marking of glass during production

(75) Inventor: Rainer Thomas, Wernigerode (DE)

Correspondence Address: VANGELIS ECONOMOU;RYNDAK & SURI LLP, 200 W.MADISON ST., CHICAGO, IL, 60606, US

(73) Assignee: boraglas GmbH

(21) Appl. No.: 11/185,177

(22) Filed: Jul. 20, 2005

(30) Foreign Application Priority Data
Jul. 21, 2004 (DE) DE 102004035239.9

(51) Int. Cl. C23C 16/52; C03C 15/00; C03B 18/18

(52) U.S. Cl. 427/8; 427/372.2; 65/30.13; 65/30.11; 65/29.19

(57) ABSTRACT

The present invention relates to a novel, reliable, and forgery-proof method for temperature-induced marking of glass and coating compositions for use in this marking and detection methods for checking the performance of the heat treatment in glass.

The present invention relates to a novel, reliable, and forgery-proof method for temperature-induced marking and/or test marking of glass, as well as coating compositions for use in this marking and detection methods for checking the performance of a heat treatment in glass.

A known problem in glass, particularly in large-area facade glass, is the spontaneous occurrence of fractures because of temperature changes, which result in tensions in the glass. For this reason, since the beginning of 2003 a hot storage test (HST) has been required by law before the installation of facade glass, in which the glass is subjected to a heat treatment of 4 hours at 280° C. If this test is performed correctly, the risk of a later spontaneous fracture is significantly less.

However, for reasons of time and cost, the test is frequently shortened and/or performed at a temperature which is too high or too low. Therefore, recently a marking system has been offered in which the glass surface is marked with a thermochromic dye, which displays a color change upon heating over 280° C. and decomposes upon heating to a temperature of significantly more than 280° C. However, these markers of the related art (e.g., SECURIT H) have the disadvantage that the color change frequently occurs even before the required time of 4 hours has passed and therefore a reliable test result is not provided. In addition, the marking is located externally on the glass surface and is therefore accessible to forgery attempts.

Accordingly, the object of the present invention is to provide an improved, reliable, and forgery-proof method for temperature-induced marking and/or test marking of glass and to provide a detection method for checking the performance of a heat treatment in glass.

These objects are achieved by methods and coating compositions having the features of claims 1, 19, 21, and 22. Advantageous embodiments of the present invention are the subject of the dependent claims.

In contrast to the above-mentioned related art, the marking and detection methods according to the present invention are based on a mark in the glass interior. Such marks are known in principle, but were performed at very much higher temperatures (DD 215 776) and/or using a laser (DE 102 50 408).

The present invention is based on the surprising finding that even at a temperature of less than 400° C., particularly precisely in the desired special temperature range of approximately 280° C. to 320° C., reliable, solely temperature-induced marking of glass is possible in that a coating composition which contains at least one metal compound, preferably a silver compound, is applied to the glass and subsequently a heat treatment is performed at the cited temperatures. To achieve the marking, preferably a heat treatment of several hours, for example, for at least 4 hours, at a temperature of less than 400° C., preferably between approximately 280° C. and approximately 320° C., is provided.

In the course of this, the metal ions of the metal compound diffuse into the glass and are reduced there by ions of the glass (such as Sn²⁺) or external reducing agents (such as H₂) to the corresponding metal atoms, which aggregate to particles and discolor the glass. This particle formation, which is decisive for the resulting discoloration, was very surprising at the preferred low temperature of approximately 280 to approximately 320° C., i.e., significantly below the glass transition temperature of approximately 550° C.

The discoloration, particularly a contrast increase or absorption elevation, may even be determined visually without optical aids. In addition, the degree of discoloration is a function of the duration of the heat treatment.

The reducing ions of the glass are predominantly tin ions. Therefore, when marking the commercially available “float glass”, which has a relatively tin-rich surface (bath side) and a relatively tin-poor surface (air side), the coating composition is applied to the relatively tin-rich surface in order to encourage the reduction reaction.

The color tone and/or the strength of the discoloration of the glass is a function of the duration and temperature of the heat treatment. This means that the present invention provides not only a marking method and a qualitative proof of an implemented heat treatment and marking of the glass, but rather also allows a quantitative determination of the duration and/or temperature of the heat treatment, by comparing the marked sample glass to a reference.

Accordingly, in a preferred aspect, the present invention relates to a detection method for determining the duration and/or applied temperature of a heat treatment in a glass, to which a coating composition as defined in one of claims 1, 4-7, and 11 or a coating composition according to one of claims 19 and 20 has been applied and which was subjected to such a heat treatment, the discoloration of the glass being compared visually to the discoloration of a reference glass which was subjected to a known heat treatment or measured using a photometer, such as a spectrometer, and compared to reference values.

In an especially preferred aspect, the present invention particularly relates to a detection method for testing whether a glass, to which a coating composition as defined in one of claims 1, 4-7, and 11 or a coating composition according to one of claims 19 and 20 was applied, has been subjected to a heat treatment of 4 hours at 280-320° C., the discoloration of the glass being visually compared to the discoloration of a reference glass which was known to have been subjected to this heat treatment, or measured using a photometer, such as a spectrometer, and compared to reference values.

In principle, all metal compounds whose metal ions diffuse in the glass at a temperature of less than 400° C., preferably at a temperature between 280 and 320° C., and are capable of being reduced by the ions of the glass and to aggregate to particles, for example, are suitable as reducible metal compounds for the coating composition. These are preferably gold, silver, or copper compounds, especially preferably silver compounds, since silver ions are easy to reduce and silver particles provide an especially clear brown discoloration.

The reducible metal compounds used, particularly silver compounds, preferably have a high solubility in water or an organic solvent. This makes the production of a suitable coating composition easier.

Preferred, non-restrictive examples of suitable silver compounds are silver salts, such as silver nitrate, silver fluoride, silver acetate, silver chlorate, silver perchlorate, silver citrate, etc., as well as silver complexes.

In a preferred embodiment of the present invention, the coating composition also includes at least one other metal compound in addition to the reducible metal compound. This second metal compound may be used for the purpose of reducing the melting point of the mixture, for example, and accelerating the diffusion of the reducible metal ions into the glass. An example of this is potassium nitrate in combination with silver nitrate. The relative proportions of potassium nitrate and silver nitrate are especially preferably such that there is a eutectic mixture.

In a special embodiment, the coating composition also includes a zirconium compound in addition to the silver compound. Advantages for an especially high-contrast darkening effect or pigmentation of the treated glass may result from this.

If desired, the coating composition may also contain a reducing agent, capable of reducing the metal ions of the reducible metal compound. Reducing agents preferably include copper(I) and/or tin(II) and/or iron(II) and/or lead(II) and/or cobalt(II) and/or titanium(II) compounds and/or complex systems such as iridium(II) hexachloride and/or cyanoferrate(II). The reducing agents are capable of diffusing into the glass as well and amplifying the reduction process of the metal ions there.

The speed and the degree of the discoloration may be set if needed through the concentration of the reducible metal compound and possibly the additional reducing agent in the coating composition. The concentration of the reducible metal compound, particularly silver compound, is preferably in a range from 0.1 to 50, more preferably 1 to 30, especially preferably 4 to 14 mass-percent of the coating composition.

Further advantages in regard to the formation of especially homogeneous and stable coatings may result if the coating composition contains at least one additional substance, whereby the viscosity, the volume, the drying and evaporation rate, the wettability, and/or the storability of the coating composition can be influenced. Examples of these are disinfection agents in the case of using gelatin as a binder matrix, or leveling agents, in order to ensure good and rapid spreading of the coating medium applied to the substrate, or viscosity increasing agents and anti-settling compounds, which result in better storability of the coating medium and counteract de-emulsification, and cause better coating uniformity if the coating media are applied as pastes.

The addition of drying regulators, such as silanes, also contributes to an improvement of the uniformity of the applied coating.

Further advantages may result if the coating composition contains additives of coloring agents and/or pigments and/or adhesion promoters and/or wetting agents. The recognizability of a coating applied to the glass may be elevated using coloring agents or pigments. Furthermore, in order to keep the surface tension of the coating media as low as possible and be able to implement a coating without wetting interference on the glass or film surface, for example, wetting agents and adhesion promoters may be used in the coating mixtures. All wetting agents known per se from photographic emulsions or from other fields of coating technology may be used as such, such as fluorine surfactants, de-emulsifiers, high molecular weight alkylaryl ethers, polyethylene glycols, etc.

The weight ratio of metal compound(s) and binder will vary depending on the type of application of the coating composition.

The binder(s) used must be provided in a sufficient quantity so that the adhesion of the metal compounds and other compounds contained in the coating media with the glass surface is ensured by the binder matrix. The metal compound-binder weight ratio will typically be selected in the range from 0.05 to 8000, particularly in the range from 1 to 4000, depending on the intended application method. In special cases, however, other weight ratios may be suitable.

Any glass having a sufficient intrinsic content of reducing ions, particularly any float glass in which the discoloration is visible after the marking, is especially suitable for marking. In addition to clear glass, milky glass or glass which is previously colored per se may be used. The marking is irreversible and will not blur or weather.

According to a first embodiment of the marking method and/or test marking method according to the present invention, the glass surface is coated through an application (deposition) of the coating composition in a dissolved liquid state, preferably through spraying, pouring, rolling, or doctoring. Curved and angled surfaces may thus advantageously be coated uniformly in this way.

According to a further embodiment of the marking method according to the present invention, the coating is performed through an application of the coating composition in a solid layer state. This application preferably comprises adhesion of a self-supporting film of the coating composition (thickness preferably 5 μm or more) to the glass surface or a composite made of the coating composition and a carrier film to the glass surface. The carrier film may be pulled off before or after the heat treatment depending on its temperature stability. The film of the coating composition or the carrier film is preferably self-adhesive.

With a direct application of the coating composition, e.g., as a solution or paste, it may be washed off after the heat treatment. If desired, the binder may be optimized in regard to effective removal through washing.

In principle, all solvents which allow sufficiently high concentrations of dissolved metal compounds come into consideration as the solvent for the coating composition. Preferred examples are water, alcohols, ketones, or ethers and their mixtures. Mixtures of water and an organic solvent miscible therewith, such as a low molecular weight alcohol like ethanol, are especially preferred.

Particularly for application of the coating composition in accordance with the spraying method, solvents and/or solvent combinations which allow a sufficiently high content of metal compounds in regard to their dissolving ability and, in addition, do not coagulate the binders used, but rather allow their complete or colloidal solution, are preferred. Depending on the binder selected, these may be water, alcohols, ketones, or ethers and their mixtures, for example.

Depending on the application method, it is preferable if the solvents are miscible with one another in addition to the dissolving ability for the metal compounds and binders (polymers). For application of the coating media in the spraying method using dual-nozzle or multiple nozzle technology, this miscibility is required to a lower degree.

The natural polymers known from the production of photographic emulsions, such as gelatins, casein, albumin, polysaccharides, or artificial polymers, such as polyethylene glycols, polyvinyl alcohols, polyvinyl pyrrolidones, cellulose acetates, polyvinyl formals and butyrals, polystyrenes, copolymers made of vinyl chloride and vinyl acetate, hyaluronic acid, etc., may be used as binders, for example. Alternatively, mixtures made of multiple binders may be used.

If films are used, films made of polycarbonate, polyethylene, polyethylene terephthalate, polyethylene naphthalate, cellulose triacetate, polyvinyl chloride, polypropylenes, etc., may be used. The lowest possible film thickness is advantageous in this case, in order to achieve a high adaptation to the glass and therefore the tightest possible contact of coating composition and glass.

In the methods with application of films and also in the other cited application types of the coating media to the glass surface, the most rapid possible drying of the applied coating media is advantageous. For this purpose, there is adaptation between the content of solvents in the coating medium, the application rate and quantity, the coating thickness, and the evaporation rate of the solvent through technological measures which are known per se. The evaporation rate is to be set as high as possible. This requires rapid heating of the applied coating without bubbles forming due to evaporating solvent and rapid removal of the evaporating solvent through suitable air conduction.

Furthermore, the technological conditions are to be selected so that the drying rate is higher than the crystallization rate of the dissolved metal compounds, in order to obtain the smallest possible crystals of the metal compounds in the coating on the glass or on the films used. Small crystals of the metal compounds contribute significantly to the contact with the glass surface being able to be as intimate as possible.

The coating thickness of the applied coating composition is also a parameter which influences the rate and the degree of discoloration. Suitable, non-restrictive ranges are 50 nm to 50 μm, preferably 100 nm to 10 μm, especially preferably approximately 1-5 μm.

The following, non-restrictive example explains the present invention on the basis of a preferred embodiment.

### EXAMPLE

A coating composition was produced from the following components:

4 ml AgNO₃ solution (50% in H₂O)

10 ml binder: 6 ml Klucel H (a hydroxypropyl cellulose) in 1% ethanol (in H₂O)+4 ml PEO (polyethylene oxide) 8000 in 1% H₂O (in ethanol)

wetting agent (facultative): 2 ml Triton 100 in 10% ethanol (in H₂O)

14.15 ml H₂O

12.35 ml ethanol,

which had a concentration of 8.1 % (mass-percent) AgNO₃ and a volume ratio of ethanol:water of 1:1 in the composition.

This coating composition was applied at a volume of 50 μl to an area of 1 cm² of the tin-rich bath side of float glass. After a drying step at room temperature, the glass was thermally treated at 280° C. for 4 hours and subsequently the solution was removed through rinsing with water. A 1 cm² large brown discoloration of the glass was now located in the interior of the glass.

1. A method for temperature-induced marking of glass, wherein a coating composition, which contains at least one metal compound and a binder, is applied to the glass and the glass is subjected to a heat treatment of several hours at a temperature of less than 400° C., metal ions from the coating composition diffusing into the glass and being reduced by ions in the glass or by external reducing agents to the corresponding metal atoms, which aggregate into particles and discolor the glass.

2. The method according to claim 1, wherein the heat treatment is performed at a temperature in the range from about 280° C. to about 320° C.

3. The method according to claim 1 wherein the duration of the heat treatment is at least 4 hours.

4. The method according to claim 1, wherein the coating composition further comprises at least one material selected from a group consisting of a silver compound, a gold compound or a copper compound.

5. The method according to claim 1, wherein the coating composition further comprises silver nitrate.

6. The method according to claim 5 wherein the coating composition further comprises a mixture of silver nitrate and potassium nitrate.

7. The method according to claim 6 wherein the coating composition further comprises a eutectic mixture of silver nitrate and potassium nitrate.

8. The method according to claim 1, wherein the glass is a glass having a relatively tin-rich surface and a relatively tin-poor surface and the coating composition is applied to the relatively tin-rich surface.

9. The method according to claim 1, wherein at least one of the degree of glass discoloration and the color of the marked glass is settable through the level of the temperature and the duration of the heat treatment.

10. The method according to claim 1, wherein a degree of discoloration predefined by a testing method occurs after 4 hours of heat treatment.

11. The method according to claim 1, wherein the concentration of the reducible metal compound in the coating composition is 1.0-30 mass percent.

12. The method according to claim 1, wherein the thickness of the coating applied to the glass is in the range from 100 nm to 10 μm.

13. The method according to claim 1, wherein the application step of applying the coating composition further comprises applying the composition when it is in a dissolved liquid state.

14. The method according to claim 13 wherein the application step of applying the coating composition further comprises a step of spraying, pouring, rolling, or doctor application.

15. The method according to claim 1, wherein the application step of applying the coating composition further comprises applying the composition in a solid layer state.

16. The method according to claim 15 wherein the application step of applying the coating composition further comprises adhesion to the glass surface of a self-supporting film containing the coating composition.

17. The method according to claim 15, wherein the application step of applying the coating composition further comprises adhesion to the glass surface of the coating composition and including a carrier film.

18. The method according to claim 16, wherein the film of the coating composition is self-adhesive and is adhered to the glass.

19. A coating composition, for temperature-induced marking of glass comprising a eutectic mixture of at least two components selected from the group consisting of metal salts and a binder.

20. The coating composition according to claim 19 wherein the eutectic mixture of metal salts further comprises a mixture of silver nitrate and potassium nitrate.

21. A detection method for determining the duration and/or applied temperature of a heat treatment in a glass, to which a coating composition, which contains at least one metal compound and a binder, as has been applied and which has been subjected to a heat treatment, the discoloration of the glass being compared to the discoloration of a reference glass which was subjected to a known heat treatment or being measured using a photometer and compared to reference values.

22. A detection method for testing whether a glass, to which a coating composition containing at least one metal compound and a binder has been applied, has been subjected to a heat treatment of 4 hours at 280-320° C., the method comprising providing a reference glass known to have been subjected to such heat treatment, and comparing the discoloration of the glass to the discoloration of the reference glass, or being measured using a photometer and compared to reference values.

23. The detection method according to claim 21 wherein the coating composition for temperature-induced marking of glass, further comprises comparing the glass with the reference glass in which both glasses include a coating composition comprising a eutectic mixture of at least two components selected from the group consisting of metal salts and a binder.

24. The detection method according to claim 23, wherein the eutectic mixture of metal salts further comprises silver nitrate and potassium nitrate.

25. The detection method according to claim 22 wherein the coating composition for temperature-induced marking of glass, further comprises comparing the glass with the reference glass in which both glasses include a coating composition comprising a eutectic mixture of at least two components selected from the group consisting of metal salts and a binder.

26. The detection method according to claim 25, wherein the eutectic mixture of metal salts further comprises silver nitrate and potassium nitrate.

27. The method according to claim 18, wherein the carrier film is self-adhesive and is adhered to the glass.
